(19) United States
(12) Patent Application Publication
(10) Pub. No.: US 2022/0285580 A1
(43) Pub. Date: Sep. 8, 2022

(54) Semiconductor Light-Emitting Device

(71) Applicants: Toytoda Gosei Co., LTD., Kiyosu-shi (JP); Meijo University, Nagoya-shi (JP)

(72) Inventors: Koji Okuno, Kiyosu-shi (JP); Koichi MUZUTANI, Kiyosu-shi (JP); Masaki OYA, Kiyosu-shi (JP); Kazuyoshi IIDA, Kiyosu-shi (JP); Satoshi KAMIYAMA, Nagoya-shi (JP); Tetsuya TEKEUCHI, Nagoya-shi (JP); Motoaki IWAYA, Nagoya-shi (JP); Isamu AKASAKI, Nagoya-shi (JP)

(21) Appl. No.: 17/673,006

(22) Filed: Feb. 16, 2022

(30) Foreign Application Priority Data
Mar. 4, 2021 (JP) 2021-034859

(51) Int. Cl. H01L 33/08; H01L 33/06; H01L 33/14; H01L 33/24; H01L 33/38; H01L 33/42

(52) U.S. Cl. CPC H01L 33/08; H01L 33/06; H01L 33/145; H01L 33/24; H01L 33/387; H01L 33/42

(57) ABSTRACT

The semiconductor light-emitting device includes an n-type semiconductor layer, a plurality of columnar semiconductors on the n-type semiconductor layer, a buried layer filling in a space between the columnar semiconductors, and a current suppression region suppressing a current. The columnar semiconductors has a hexagonal column and an active layer covering the hexagonal column. The hexagonal column has a hexagonal first surface and a second surface opposite to the first surface. The first surface of the columnar semiconductors faces the base layer. The second surface of the columnar semiconductors faces the current suppression region.

### BACKGROUND OF THE INVENTION

### Field of the invention

The present invention relates to a semiconductor light-emitting device.

### Background Art

A semiconductor light-emitting device emits light through recombination of an electrons with a hole in an active layer. Conventionally, a fiat sheet well layer has been used as an active layer. Recently, an active layer having a three-dimensional structure such as column has been studied.

For example, Japanese Patent Application Laid-Open (kokai) No. 2019-012744 discloses a semiconductor light-emitting device including an n-type nanowire layer 1031, an active layer 1032, a p-type semiconductor layer 1033, a p+ type layer 1034, and an n+ type layer 1035 (paragraph [0038]). It also discloses that a semiconductor layer 104 fills in a space between columnar semiconductor layers 103 (paragraph [0037]).

In semiconductor having a nanowire structure disclosed in Japanese Patent Application Laid-Open (kokai) No. 2019-012744, the active layer 1032 has a hexagonal cylindrical shape (FIGS. 1 and 2). The active layer 1032 disposed on the side surface of the n-type nanowire layer 1031 has a part parallel to a m-plane. The active layer 1032 disposed opposite to a substrate in the n-type nanowire layer 1031 has a part parallel to a c-plane or a r-plane.

A m-plane is a non-polar plane. In an active layer formed parallel to a m-plane, no polarization is generated Therefore, in such an active layer, Quantum-confined Stark Effect (QCSE) does not occur. Thereby, internal quantum efficiency is expected to be improved. In the techniques of Japanese Patent Application Laid-Open (kokai) No. 2019-012744, an active layer parallel to a c-plane or a r-plane in addition to a m-plane is formed. The light-emitting layers formed on the m-plane, the c-plane, and the r-plane are different in emission wavelength and quality from each other. When a current flows to the device, the light-emitting layers on the m-plane, the c-plane, and the r-plane emit light. Therefore, the current being injected into the m-plane is reduced. Problems of variations in emission wavelength or reduction in emission efficiency of the entire device are caused.

### SUMMARY OF THE INVENTION

The present invention has been conceived for solving the aforementioned problems. Thus, an object of the present invention is to provide a semiconductor light-emitting device having an active layer with a three-dimensional microstructure, of which light-emitting layers selectively emit light.

In a first aspect of the present invention, there is provided a semiconductor light-emitting device comprising a base layer, a plurality of columnar semiconductors on the base layer, a buried layer filling in a space between the columnar semiconductors, and a current suppression region suppressing a current. A plurality of columnar semiconductors has a hexagonal column, and an active layer covering the hexagonal column. The hexagonal column has a hexagonal first surface and a second surface opposite to the first surface. The first surface of the columnar semiconductors faces the base layer. The second surface of the columnar semiconductors faces the current suppression region. That is, the current suppression region is on a top of the columnar semiconductor.

In the first aspect of the present invention, the current suppression region is preferably a semiconductor having an electrical resistivity higher than the electrical resistivity of the columnar semiconductors. The current suppression region may be a space. The columnar semiconductor is preferably arranged in a plane lattice, and a space or a pit is preferably formed in a region disposed at a face center of a unit cell of the plane lattice. The buried layer may have a first layer covering the columnar semiconductors, and a second layer covering the first layer, and the impurity concentration of the second layer may be higher than the impurity concentration of the first layer. A tunnel junction part may be formed, the tunnel junction part may have a p-type layer and an n-type layer, and the tunnel junction part may be disposed between the active layer and the buried layer. An anode electrode and a conductive oxide layer may be formed, the conductive oxide layer may be disposed between the buried layer and the anode electrode.

In the semiconductor light-emitting device, a current hardly flows to the current suppression region. Thereby, light emission is suppressed in a c-plane or a r-plane which may exist in a vicinity of the current suppression region. The active layer having a m-plane emits light at a high efficiency. Therefore, in this semiconductor light-emitting device, variations in wavelength or increase in full width at half maximum, and reduction in emission efficiency hardly occur.

This specification provides a semiconductor light-emitting device in which light is selectively emitted from the light-emitting layer of the semiconductor light-emitting device including an active layer having a three-dimensional microstructure.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a perspective view showing the structure of a semiconductor light-emitting device 100 according to a first embodiment;

FIG. 2 is a schematic view showing a cross section of the semiconductor light-emitting device 100 according to the first embodiment;

FIG. 3 shows the internal structure of a columnar semiconductor 130 of the semiconductor light-emitting device 100 according to the first embodiment;

FIG. 4 is a cross-sectional view of IV-IV in FIG. 3;

FIG. 5 is a second cross-sectional view of V-V in FIG. 3;

FIG. 6 is a view (part 1) for explaining a method for producing the semiconductor light-emitting device 100 according to the first embodiment;

FIG. 7 is a view (part 2) for explaining a method for producing the semiconductor light-emitting device 100 according to the first embodiment;

FIG. 8 is a view (part 3) for explaining a method for producing the semiconductor light-emitting device 100 according to the first embodiment;

FIG. 9 is a view (part 4) for explaining a method for producing the semiconductor light-emitting device 100 according to the first embodiment;

FIG. 10 is a view (part 5) for explaining a method for producing the semiconductor light-emitting device 100 according to the first embodiment;

FIG. 11 is a view (part 6) for explaining a method for producing the semiconductor light-emitting device 100 according to the first embodiment;

FIG. 12 is a view (part 7) for explaining a method for producing the semiconductor light-emitting device 100 according to the first embodiment;

FIG. 13 is a view (part 8) for explaining a method for producing the semiconductor light-emitting device 100 according to the first embodiment;

FIG. 14 is a schematic view for explaining effect of the semiconductor light-emitting device 100 according to the first embodiment;

FIG. 15 shows the internal structure of a columnar semiconductor 230 of a semiconductor light-emitting device 200 according a second embodiment;

FIG. 16 is a schematic view showing the planar structure of a semiconductor light-emitting device 300 according to a third embodiment;

FIG. 17 is a schematic view showing the relationship between cross section of XVII-XVII in FIG. 16 and average refractive index distribution;

FIG. 18 is a schematic view showing the relationship between cross section of XVIII-XVIII in FIG. 16 and average refractive index distribution;

FIGS. 19A and 19B are a diagram showing the case when a columnar semiconductor 130 is arranged in three rows;

FIG. 20 is a schematic view of the structure of a semiconductor light-emitting device 400 according to a fourth embodiment;

FIG. 21 is a schematic view of the structure of a semiconductor light-emitting device 500 according to a fifth embodiment.

### DETAILED DESCRIPTION OF PREFERRED EMBODIMENTS

With reference to the drawings, specific embodiments of the semiconductor light-emitting device as examples will next be described in detail. However, these embodiments should not be construed as limiting the invention thereto. The semiconductor light-emitting device includes a LED and a laser diode (LD). The below-described depositing structure of the layers of the semiconductor light-emitting device and the electrode structure are given only for the illustration purpose, and other depositing structures differing therefrom may also be employed. The thickness of each of the layers shown in the drawings is not an actual value, but a conceptual value.

### First Embodiment

### 1. Semiconductor Light-Emitting Device

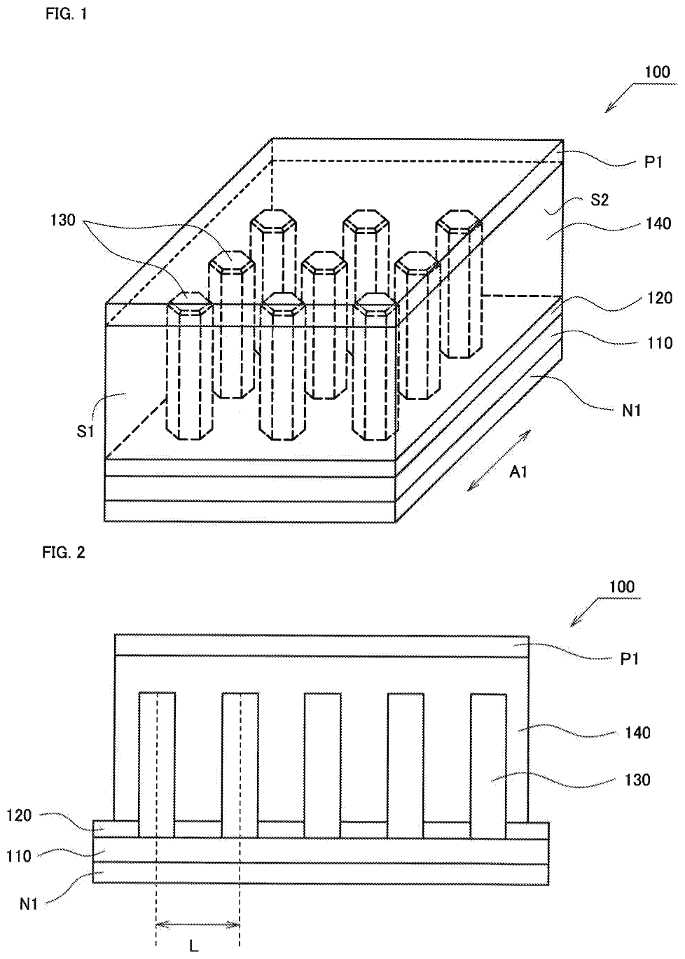

FIG. 1 is a perspective view showing the structure of a semiconductor light-emitting device 100 according to a first embodiment. The semiconductor light-emitting device 100 includes an active layer having a three-dimensional shape. As shown in FIG. 1, the semiconductor light-emitting device 100 includes a substrate 110, a mask 120, a columnar semiconductor 130, a buried layer 140, a cathode electrode N1, and an anode electrode P1.

The substrate 110 is a substrate for supporting a mask 120, a columnar semiconductor 130, and a buried layer 140.

The mask 120 is made of a material on which semiconductor does not grow. As described later, the mask 120 has a through hole. The mask 120 is preferably a transparent insulating film. In this case, the mask 120 hardly absorbs light. A current preferably flows to the columnar semiconductor 130 without through the mask 120. The material of the mask 120 includes, for example, SiO₂, SiNx, and Al₂O₃.

The columnar semiconductor 130 is a columnar Group III nitride semiconductor. The columnar semiconductor 130 is a semiconductor selectively grown from the surface of the semiconductor exposed in the opening of the mask 120. columnar semiconductor 130 has a hexagonal columnar shape. A cross section perpendicular to the central axis direction of the columnar semiconductor 130 is a regular hexagon or a flat hexagon.

The buried layer 140 is a layer for filling in a space between the columnar semiconductors 130. The buried layer 140 covers the columnar semiconductor 130. The buried layer 140 is made of, for example, n-type GaN.

The cathode electrode N1 is formed on the substrate 110.

The anode electrode P1 is formed on the buried layer 140. The anode electrode P1 may be formed on a semiconductor layer other than the buried layer 140.

### 2. Columnar Semiconductor

### 2-1. Arrangement of Columnar Semiconductor

FIG. 2 is a schematic view showing a cross section of the semiconductor light-emitting device 100 according to the first embodiment. The columnar semiconductor 130 is disposed in a square lattice. As shown in FIG. 2, a plurality of columnar semiconductors 130 are periodically disposed at a first pitch interval L.

The height of the columnar semiconductor 130 is, for example, 0.25 μm to 5 μm. The diameter of the columnar semiconductor 130 is, for example 50 nm to 500 nm. Hereinafter, a diameter refers to a distance between vertices located on a diagonal line of a hexagon. When a hexagon has long sides, a diameter refers to a distance between vertices located on a diagonal line parallel to the long side of the hexagon. A first pitch interval L of the columnar semiconductor 130 is, for example, 0.27 μm to 5 μm. Hereinafter, pitch interval refers to a distance between the center points of the hexagons. These values are merely examples, and other values may be employed.

### 2-2. Internal Structure of Columnar Semiconductor

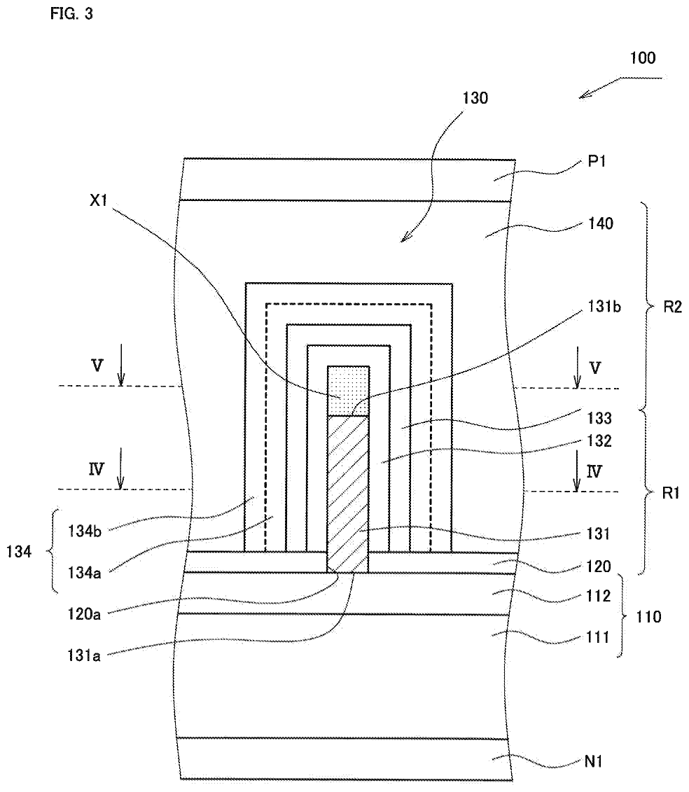

FIG. 3 shows the internal structure of a columnar semiconductor 130 of the semiconductor light-emitting device 100 according to the first embodiment.

The substrate 110 includes a conductive base material 111, and an n-type semiconductor layer 112. The conductive base material 111 supports the n-type semiconductor layer 112, and the semiconductor layers thereabove. The conductive base material 111 is, for example, a GaN substrate.

The n-type semiconductor layer 112 is a base layer for growing a columnar semiconductor 130. A part of the n-type semiconductor layer 112 is exposed in the opening 120a of the mask 120. The n-type semiconductor layer 112 is, for example, an n-type GaN layer or an n-type AlGaN layer. These are merely examples, and other structures may be employed.

The columnar semiconductor 130 includes an n-type columnar semiconductor 131, an active layer 132, a p-type cylindrical semiconductor 133, a tunnel junction part 134, and a current suppression region X1.

The side surface of the n-type columnar semiconductor 131 is a m-plane or a plane close to a m-plane. The m-plane is a non-polar plane. Therefore, in the active layer 132, the deterioration of the emission efficiency caused by piezo-polarization is hardly observed.

The n-type columnar semiconductor 131 is a hexagonal column. The side surface of the hexagonal column is a m-plane. The top surface of the hexagonal column is a c-plane. A cross section perpendicular to the axial direction of the hexagonal column is a regular hexagon or a flat hexagon. The n-type columnar semiconductor 131 has a first surface 131a and a second surface 131b. The first surface 131a is a shape of the surface exposed in the opening 120a of the mask 120. The second surface 131b is a hexagon. second surface 131b is a surface opposite to the first surface 131a. The first surface 131a oppositely contacts with the n-type semiconductor layer 112. The second surface 131b oppositely contacts with the current suppression region X1. The n-type columnar semiconductor 131 is a semiconductor layer selectively grown in a column shape from the n-type semiconductor layer 112 exposed in the opening 120a of the mask 120. The n-type columnar semiconductor 131 is actually grown in a lateral direction as well. Therefore, the diameter of the n-type columnar semiconductor 131 is slightly larger than the width of the opening 120a of the mask 120. The n-type columnar semiconductor 131 is, for example, an n-type GaN layer.

The active layer 132 covers the n-type columnar semiconductor 131 and the current suppression region X1. The active layer 132 is formed around the n-type hexagonal columnar semiconductor 131 and the current suppression region X1. Therefore, the active layer 132 has a hexagonal cylindrical shape. The active layer 132 includes, for example, one to five well layers, and a barrier layer sandwiching the well layers. A plate surface of the substrate 110 is a c-plane. The well layer of the active layer 132 is formed along the m-plane. Therefore, the well layer of the active layer 132 is disposed almost perpendicular to the main surface of the substrate 110. However, the top of the active layer 132 covers the top of the current suppression region X1. The top of the active layer 132 has at least one of a c-plane and a r-plane. The top of the active layer 132 may be almost parallel to the main surface of the substrate 110. For example, the well layer is an InGaN layer, and the barrier layer is an AlGaInN layer.

The p-type cylindrical semiconductor 133 is formed around the active layer 132 having a hexagonal cylindrical shape. Therefore, the p-type cylindrical semiconductor 133 has a hexagonal cylindrical shape. The p-type cylindrical semiconductor 133 is directly in contact with the active layer 132, but not in contact with the n-type columnar semiconductor 131. Moreover, the p-type cylindrical semiconductor 133 is in contact with the tunnel junction part 134. The p-type cylindrical semiconductor 133 is, for example, a p-type GaN layer.

The tunnel junction part 134 is formed around the p-type cylindrical semiconductor 133. The tunnel junction part 134 is disposed between the active layer 132 and the buried layer 140. The tunnel junction part 134 has a hexagonal cylindrical shape. The tunnel junction part 134 has a p⁺-type layer 134a and an n⁺-type layer 134b. The p⁺-type layer 134a is an inner layer, and the n⁺-type layer 134b is an outer layer. The p⁺-type layer 134a is in contact with the p-type cylindrical semiconductor 133. The n⁺-type layer 134b is in contact with the buried layer 140.

The current suppression region X1 suppresses a current. The current suppression region X1 is disposed at the top of the n-type columnar semiconductor 131. The current suppression region X1 is in a position farther than the n-type columnar semiconductor 131 from the substrate 110. The current suppression region X1 is surrounded by the n-type columnar semiconductor 131 and the active layer 132 in a state in contact with the n-type columnar semiconductor 131 and the active layer 132. The current suppression region X1 is a semiconductor having an electrical resistivity higher than that of the columnar semiconductor 130. The electrical resistivity of the current suppression region X1 is sufficiently higher than the electrical resistivity of the n-type columnar semiconductor 131 and the active layer 132. The material of the current suppression region X1 is, for example, undoped-GaN. Undoped-GaN is GaN which is not doped with a dopant for generating carriers.

### 2-3. First Cross-Sectional Shape

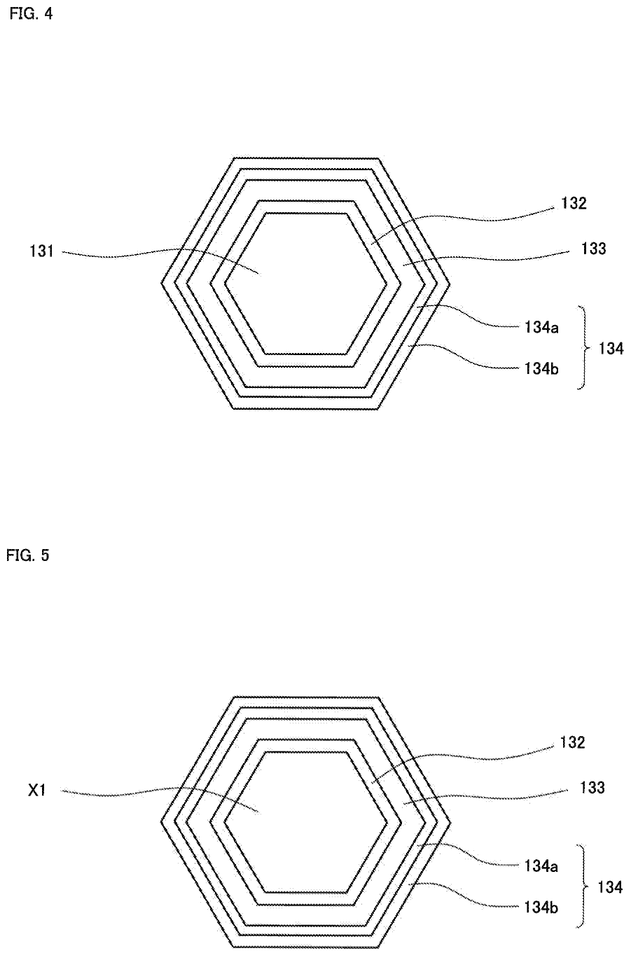

FIG. 4 is a first cross-sectional view of IV-IV in FIG. 3. FIG. 4 shows a cross section parallel to the plate surface of the substrate 110 in the columnar semiconductor 130. As shown in FIG. 4, a cross section perpendicular to the axial direction in the columnar semiconductor 130 has a regular hexagonal shape. The n-type columnar semiconductor 131, the cylindrical active layer 132, and the p-type cylindrical semiconductor 133 are disposed inside the hexagonal columnar semiconductor 130.

### 2-4. Second Cross-Sectional Shape

FIG. 5 is a second cross-sectional view of V-V in FIG. 3. FIG. 5 shows a cross section parallel to the substrate 110 in the columnar semiconductor 130. As shown in FIG. 5, a cross section perpendicular to the axial direction in the columnar semiconductor 130 has a regular hexagonal shape. The columnar current suppression region X1, the cylindrical active layer 132, and the p-type cylindrical semiconductor 133 are disposed inside the hexagonal columnar semiconductor 130.

### 3. Method for Producing Semiconductor Light-Emitting Device

### 3-1. Preparing Substrate

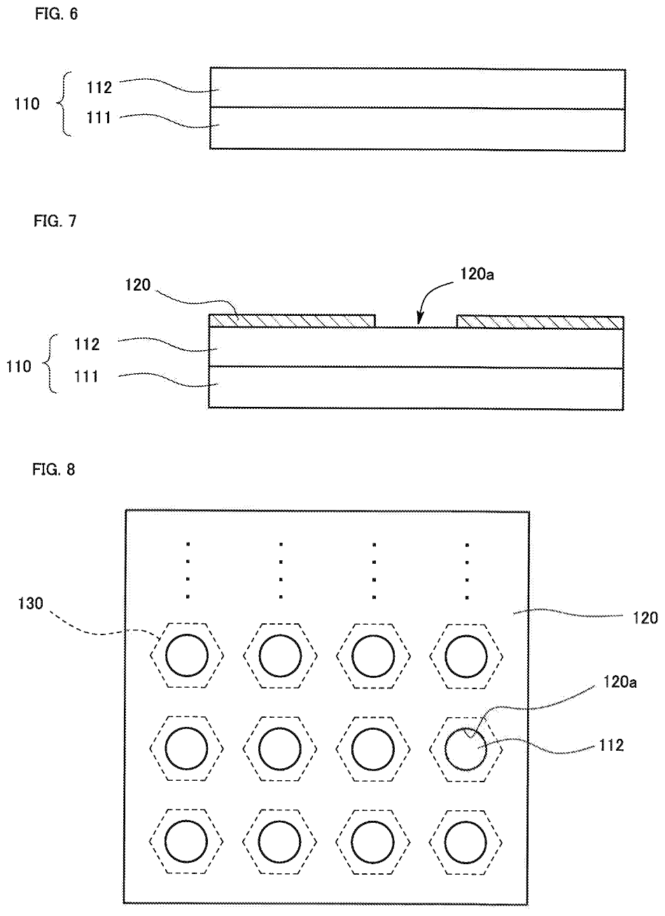

As shown in FIG. 6, a substrate 110 is prepared. The substrate 110 is formed by depositing the n-type semiconductor layer 112 on the conductive base material 111.

### 3-2. Forming Mask

As shown in FIGS. 7 and 8, a mask 120 is formed on the n-type semiconductor layer 112 of the substrate 110. A plurality of openings 120a are formed to expose the n-type semiconductor layer 112 in the mask 120. For that, etching and other techniques may be employed.

FIG. 8 is a view showing the arrangement of the openings 120a of the mask 120. FIG. 8 is a view of the substrate 110 viewed from a direction perpendicular to the plate surface of the substrate 110. In FIG. 8, the shape of the columnar semiconductor 130 is drawn with a dotted line for reference. As shown in FIG. 8, the openings 120a of the mask 120 are circles and are arranged in a square lattice. The openings 120a of the mask 120 are arranged in a plane lattice to the substrate 110 and the n-type semiconductor layer 112. Lattice arrangement shown in crystallographic restriction theorem is preferable. Plane lattice is, for example, a diagonal lattice, a hexagonal lattice, a square lattice, a rectangular lattice, and a parallel lattice. Group III nitride semiconductor has a Wurtzite structure. Therefore, a hexagonal lattice, a square lattice, and a rectangular lattice are preferable.

By changing the shape of the opening 120a of the mask 120, the shape of the columnar semiconductor 130 can be controlled. When the shape of the opening 120a is a circle, a columnar semiconductor 130 having a cross-sectional shape close to a regular hexagon can be formed. When the shape of the opening 120a is an oval, a columnar semiconductor 130 having a cross-sectional shape close to a flat shape can be formed.

### 3-3. Forming Columnar Semiconductor

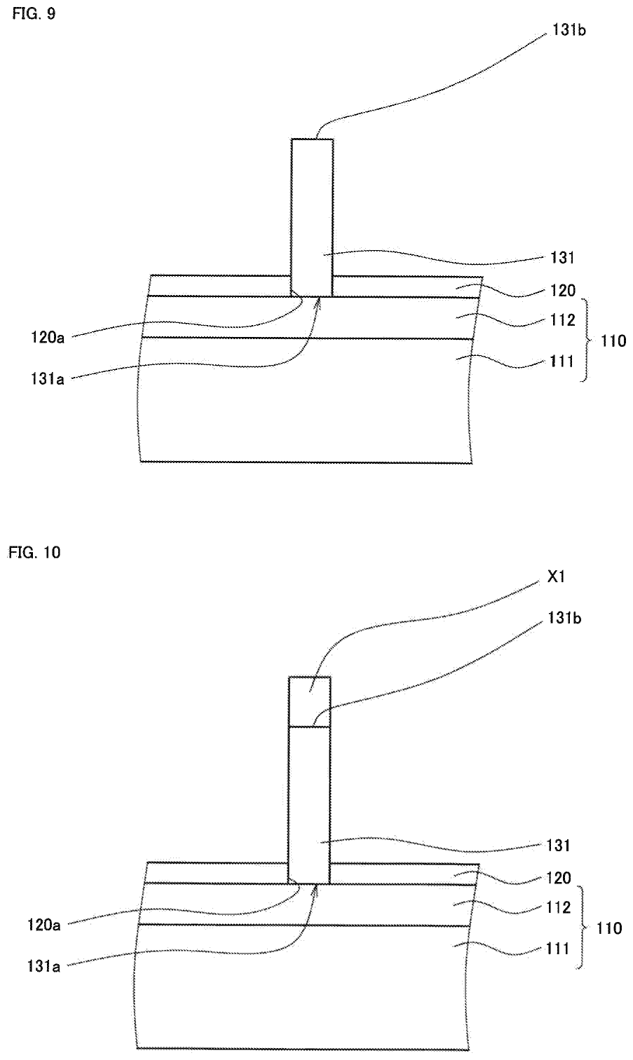

As shown in FIG. 9, the n-type hexagonal columnar semiconductor 131 is selectively grown from the n-type semiconductor layer 112 exposed in the bottom of the opening 120a of the mask 120. For that, a well-known selective growth technique may be employed. When the semiconductor layer is selectively grown, m-plane is easily exposed as a facet.

For example, semiconductor is epitaxially grown through MOCVD. The temperature of the substrate is, for example, 1,100° C. to 1,200° C. The pressure in a furnace is, for example, 1 kPa to 100 kPa.

As mentioned above, since the opening 120a of the mask 120 has a circular shape, the n-type hexagonal columnar semiconductor 131 having a cross section close to a regular hexagon is grown.

The supply of the n-type dopant gas is stopped.

As shown in FIG. 10, the current suppression region X1 starts to grow on the n-type columnar semiconductor 131. The current suppression region X1 is, for example, undoped-GaN. Undoped-GaN may slightly grow on the side surface of the n-type columnar semiconductor 131. However, the speed of growth on the side surface is sufficiently slow, and a problem hardly occurs.

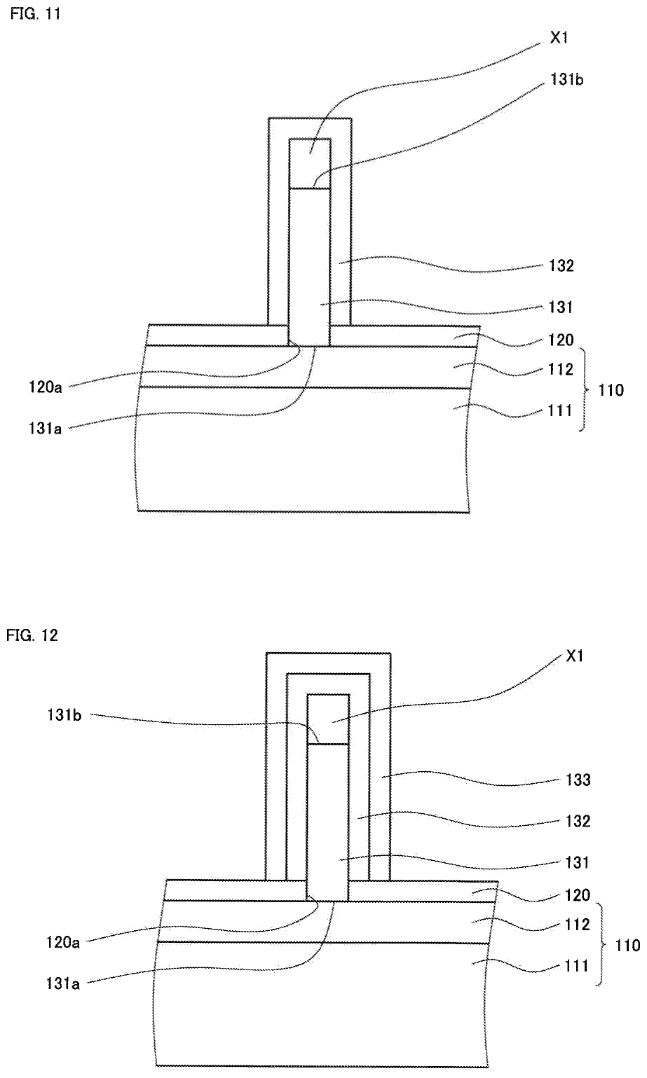

As shown in FIG. 11, the active layer 132 is formed around the n-type columnar semiconductor 131. The active layer 132 is formed on the side surface of the n-type columnar semiconductor 131 having a cross section close to a regular hexagon. The active layer 132 is also formed on the top of the n-type columnar semiconductor 131.

As shown in FIG. 12, the p-type cylindrical semiconductor 133 covering the outer periphery of the active layer 132 is formed on the active layer 132. The p-type cylindrical semiconductor 133 has a hexagonal cylindrical shape. The p-type cylindrical semiconductor 133 is formed on the side surface of the active layer 132. The p-type cylindrical semiconductor 133 is formed on the n-type columnar semiconductor 131 or on the top of the active layer 132. In this way, the columnar semiconductor 130 is formed.

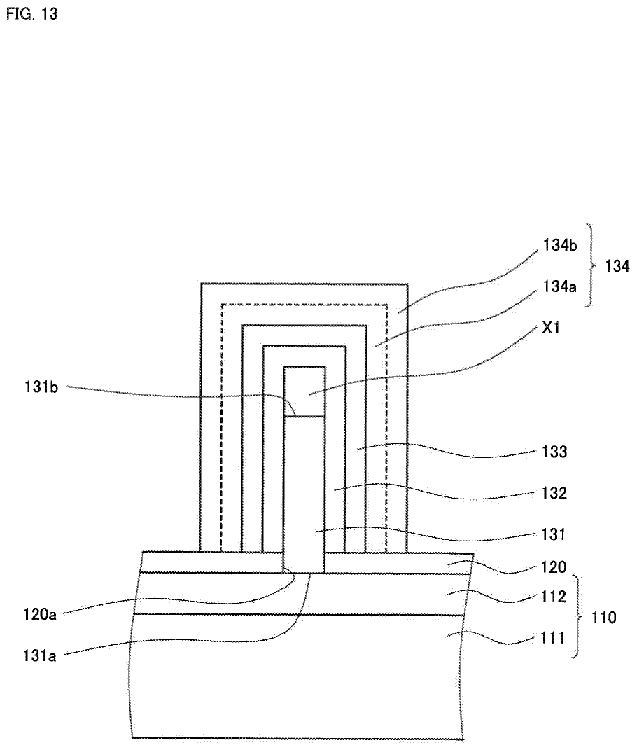

As shown in FIG. 13, the tunnel junction part 134 covering the outer periphery of the p-type cylindrical semiconductor 133 is formed on the p-type cylindrical semiconductor 133. The tunnel junction part 134 has a hexagonal cylindrical shape.

### 3-4. Forming Buried Layer

A space between the columnar semiconductors 130 is filled with the buried layer 140.

### 3-5. Forming Electrode

Subsequently, the cathode electrode N1 is formed on the n-type semiconductor layer 112 of the substrate 110. Moreover, the anode electrode P1 is formed on the buried layer 140.

### 3-6. Other Steps

In addition to the aforementioned steps, additional steps such as a heat treatment step and a step of forming a passivation film on the surface of the semiconductor layer may be carried out.

### 4. Effect of First Embodiment

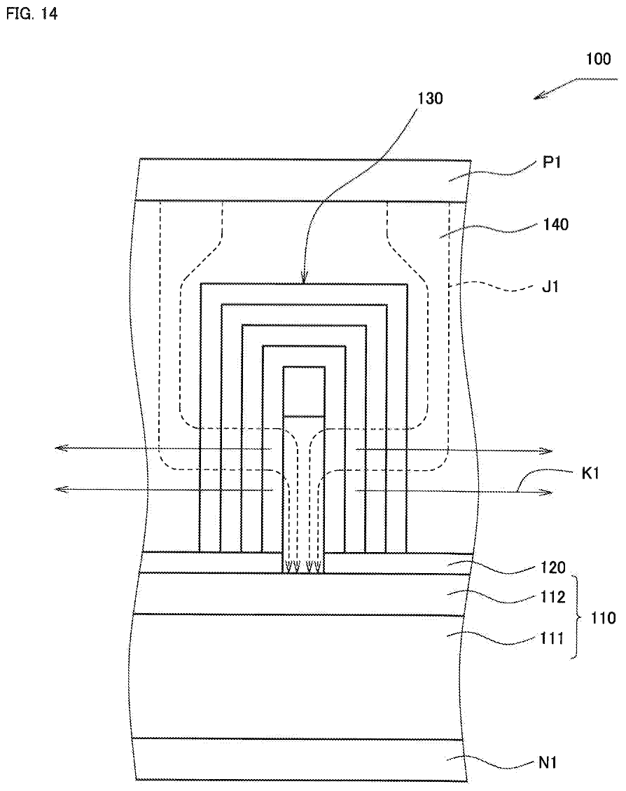

FIG. 14 is a schematic view for explaining effect of the semiconductor light-emitting device 100 according to the first embodiment. In FIG. 14, a current flows along an arrow J1. The semiconductor light-emitting device 100 includes the current suppression region X1 having a high electrical resistivity. Therefore, a current flows avoiding the current suppression region X1. As a result, the active layer 132 in a region adjacent to the current suppression region X1 hardly emits light. The light is omnidirectionally emitted from a hexagonal contact region in which the active layer 132 contacted with the n-type columnar semiconductor 131. Arrow K1 indicates propagation direction of a part of omnidirectional emitted light.

Thus, in the semiconductor light-emitting device 100, light emission is suppressed in the active layer 132 covering the current suppression region X1. That is, light emission is suppressed in a c-plane or a r-plane which may exist in a vicinity of the current suppression region X1. The active layer 132 having a m-plane emits light at a high efficiency. Thereby, variations in wavelength or increase in full width at half maximum, and reduction in emission efficiency hardly occur.

### 5. Variations

### 5-1. Conductive Oxide Layer

A conductive oxide layer may be disposed between the buried layer 140 and the anode electrode P1. The conductive oxide layer is, for example, a layer made of transparent conductive oxide such as ITO and IZO.

### 5-2. Arrangement of Columnar Semiconductor and Arrangement of Projections

A plurality of the columnar semiconductors 130 may be arranged in a honeycomb pattern. However, when the semiconductor light-emitting device 100 is used as a laser device, a plurality of columnar semiconductors 130 are preferably arranged in a square lattice because a coherent light is easily emitted.

### 5-3. Mask Pattern

The opening of the mask may have a shape other than a circle, for example, a hexagon. Even in this case, the n-type columnar semiconductor 131 grows in a hexagonal columnar shape.

### 5-4. Composition of Current Suppression Region

The composition of the current suppression region X1 may be Group III nitride semiconductor other than undoped-GaN, for example, undoped-AlGaN or Group III nitride semiconductor doped with Mg, C, O, and B. When Group III nitride semiconductor is doped with Mg, activation may not be performed. Or, the current suppression region X1 may be a high resistant layer doped with both Mg as a p-type impurity and Si as an n-type impurity. Needless to say, the current suppression region X1 may be other high resistant semiconductor.

### 5-5. Composition of Columnar Semiconductor

In the present embodiment, the n-type columnar semiconductor 131 is an n-type GaN layer, the well layer is an InGaN layer, the barrier layer is an AlGaN layer, and the p-type cylindrical semiconductor 133 is a p-type GaN layer. These are merely examples, and other Group III nitride semiconductor or other semiconductor may be employed.

### 5-6. Composition of Buried Layer

In the present embodiment, the buried layer 140 is a n-type GaN layer. However, a n-type AlGaN layer instead of a n-type GaN layer may be used as the buried layer 140. The refractive index of the AlGaN layer is smaller than the refractive index of the n-type GaN layer. Therefore, when a LD structure is formed, the efficiency of light confinement is improved. The buried layer 140 may be other n-type AlInGaN layer.

### 5-7. Region

As shown in FIG. 3, when the semiconductor light-emitting device 100 is a laser diode, the semiconductor light-emitting device 100 has the waveguide region R1 and the conductive region R2. The waveguide region R1 is a region used for laser oscillation and carrier injection into the active layer 132. The conductive region R2 is a region for current flow and light confinement.

### 5-8. Uneven Substrate

An uneven pattern may be formed on the conductive base material 111 of the substrate 110. That is, the conductive base material 111 has an uneven shaped part where projections and recesses are periodically arranged on the semiconductor layer side surface. The uneven shape includes, for example, a conical shape and a hemispherical shape. These uneven shapes are preferably arranged in a square lattice or a honeycomb pattern.

### 5-9. Reflective Layer

The semiconductor light-emitting device 100 may have a reflective layer on the backside of the substrate 110, which is opposite to the mask layer 120.

### 5-10. Electron Barrier Layer

An electron barrier layer may be formed outside the active layer 132. The electron barrier layer is made of, for example, AlGaInN.

### 5-11. Tunnel Junction Part

The tunnel junction part 134 is not necessarily formed. In that case, a space between the columnar semiconductors 130 is filled with the p-type semiconductor layer.

### 5-12. Cathode Electrode

The cathode electrode may be formed on the upper surface of the n-type semiconductor layer 112 of the substrate 110. In that case, other base material instead of the conductive base material 111 may be used. The base material is, for example, a sapphire substrate.

### 5-13. Rectangular Lattice

The columnar semiconductor 130 may be disposed at a lattice point of a rectangular lattice instead of a square lattice.

### 5-14. Inclined Surface

In FIG. 3, a c-plane and a m-plane are drawn. The surface inclined to the m-plane is not drawn. However, the inclined surface such as a r-plane may actually exist.

### 5-15. Combinations

The aforementioned variations may be combined with one another without any restriction.

### Second Embodiment

The second embodiment will next be described. The current suppression region of the second embodiment is different from the current suppression region of the first embodiment. Different points are mainly described.

### 1. Semiconductor Light-Emitting Device

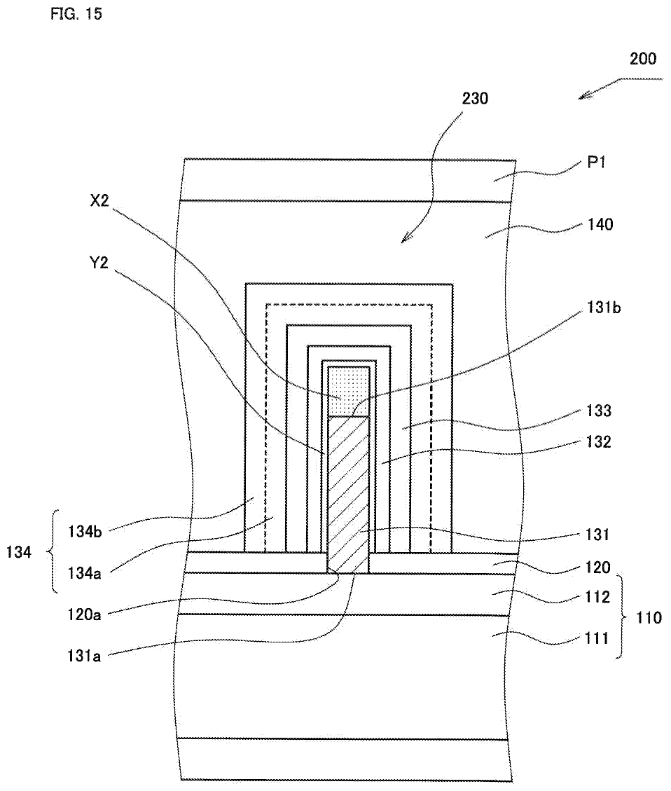

FIG. 15 shows the internal structure of a columnar semiconductor 230 of a semiconductor light-emitting device 200 according a second embodiment. As shown in FIG. 15, the semiconductor light-emitting device 200 includes a substrate 110, a mask 120, a columnar semiconductor 230, a buried layer 140, a cathode electrode N1, and an anode electrode P1.

The columnar semiconductor 230 includes an n-type columnar semiconductor 131, an active layer 132, a p-type cylindrical semiconductor 133, a tunnel junction part 134, a current suppression region X2, and a suspension part Y2. Here, the n-type columnar semiconductor 131 is preferably n-type AlGaN having a high Al composition.

The current suppression region X2 is a space. The current suppression region X2 is filled with atmosphere.

The suspension part Y2 is a semiconductor layer for forming the current suppression region X2.

### 2. Method for Producing Semiconductor Light-Emitting Device

Points different from the first embodiment will be described.

A current suppression region X2 is formed by the method disclosed in Japanese Patent Application Laid-Open (kokai) No. 2018-110172 (paragraphs [0057] to [0066]).

Firstly, an n-type columnar semiconductor 131 is formed. An. InGaN layer is formed as a decomposition layer on the n-type columnar semiconductor 131. Subsequently, an AlGaN layer is formed as a suspension part Y2. Next, an InGaN layer as the decomposition layer is decomposed by etching.

### 3. Effect of Second Embodiment

In the semiconductor light-emitting device 200 according to the second embodiment, the electrical resistivity of the current suppression region X2 is higher than the electrical resistivity of the current suppression region X1 of the first embodiment. Therefore, in the semiconductor light-emitting device 200 according to the second embodiment, light emission is further suppressed in a plane other than m-plane.

### 4. Variations

### 4-1. Decomposition Layer

The decomposition layer may be a GaN layer.

### 4-2. Others

A variation of the first embodiment may be employed.

### Third Embodiment

The third embodiment will be described. Points different from the first embodiment will be mainly described.

### 1. Semiconductor Light-Emitting Device

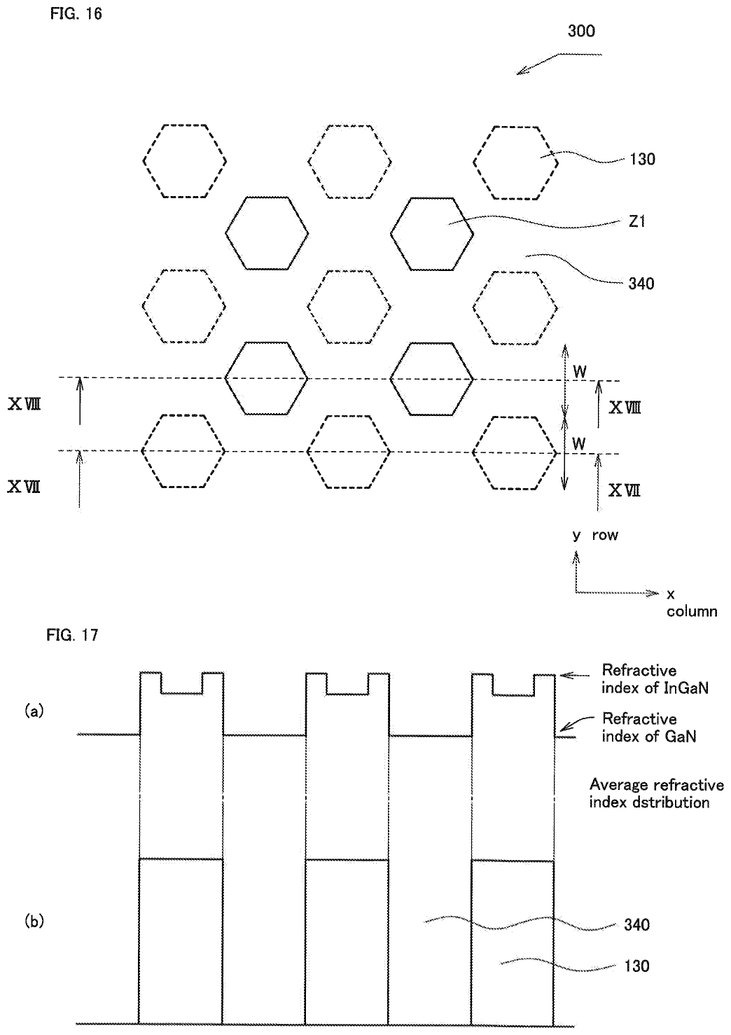

FIG. 16 is a schematic view showing the planar structure of a semiconductor light-emitting device 300 according to a third embodiment. The semiconductor light-emitting device 300 includes a substrate 110, a mask 120, a columnar semiconductor 130, a buried layer 340, a cathode electrode N1, and an anode electrode P1. As shown in FIG. 16, the semiconductor light-emitting device 300 has a space Z1 between the columnar semiconductors 130.

The columnar semiconductor 130 is arranged in a plane lattice. In FIG. 16, the columnar semiconductor 130 is arranged in a rectangular lattice. The space Z1 is formed in a region disposed at a face center of a unit cell of the plane lattice.

### 2. Refractive Index

FIG. 17 is a schematic view showing the relationship between cross section (FIG. 17(b)) of XIII-XVII in FIG. 16 and average refractive index distribution along a column in which the columnar semiconductor 130 exists. FIG. 17(a) shows an average refractive index distribution with respect to a column direction, i.e., x axis. The average refractive index is a value obtained by averaging the refractive indices in an unit width W taken along a row direction, i.e., y axis. Because InGaN of the active layer 132 is included in the columnar semiconductor 130 has a high refractive index, the average refractive index of the columnar semiconductor 130 is slightly larger than the refractive index of GaN of the buried layer 340.

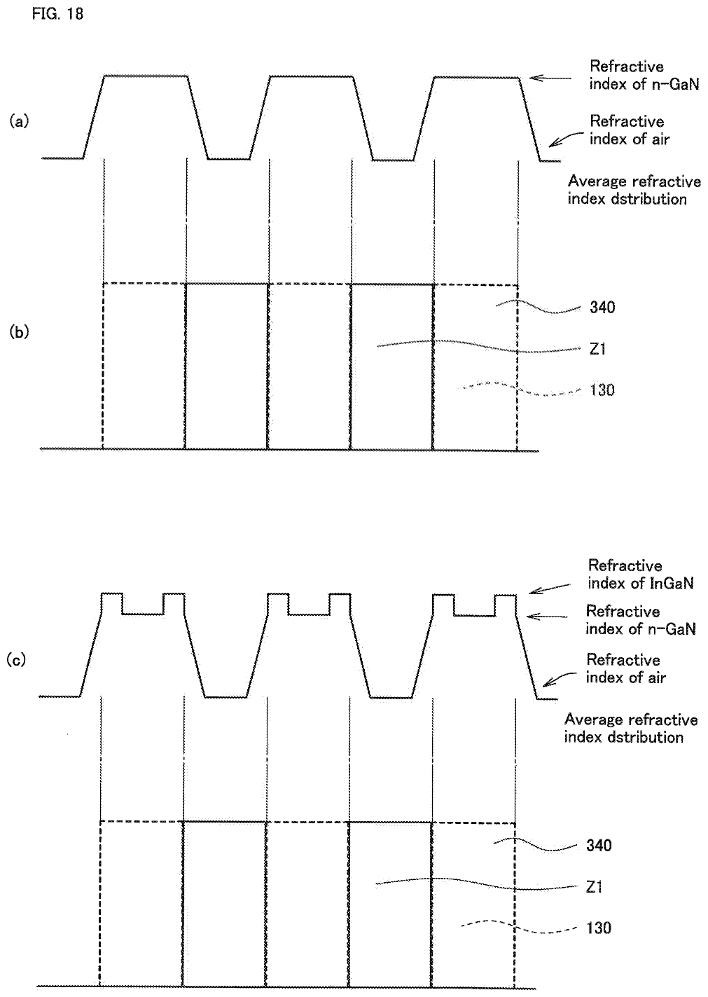

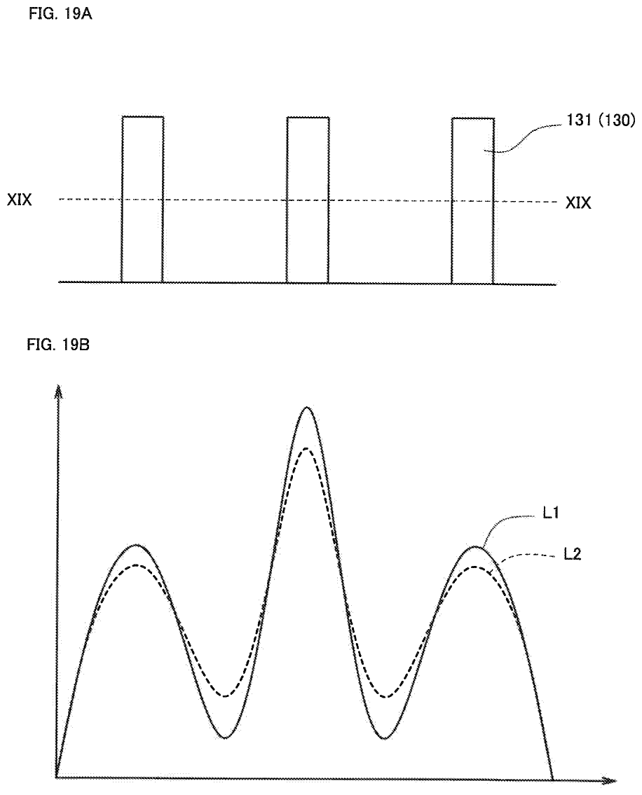

FIG. 18 is a schematic view showing the relationship between cross section (FIG. 18(b)) of XVIII-XVIII in FIG. 16 and average refractive index distribution along a column in which the space Z1 exists. FIG. 18(b) shows an average refractive index distribution with respect to a column direction, i.e., x axis. The average refractive index is a value obtained by averaging the refractive indices in an unit width W taken along a row direction, i.e., y axis. In FIG. 18(b), the columnar semiconductor 130 is drawn with a dotted line. As shown in FIG. 18(a), the average refractive index in an area in which the space Z1 exists is smaller than the refractive index of GaN of the buried layer 340. FIG. 18(c) shows a refractive index characteristic with respect to x axis of the value obtained by averaging the refractive index distribution of FIG. 17(a) and FIG. 18(a) along a light propagation direction (y axis) shown in FIG. 16. The light propagation region is a row region in which the columnar semiconductor 130 exists. The refractive index in row regions at both ends of the light propagation region is smaller than the refractive index of the light propagation region. Therefore, the light is confined in the light propagation region, and is efficiently excited in y axis direction.

If the space Z1 does not exist, the average refractive index is constant without spatially varying different from FIG. 18(a).

In the third embodiment, the average refractive index is larger in regions where rows of the columnar semiconductors 130 exist than the refractive index of the buried layer 340. Also, the refractive index is smaller in regions where rows of the spaces Z1 exist than the refractive index of the buried layer 340.

### 3. Method for Producing Semiconductor Light-Emitting Device

To form the space Z1, the formation of the buried. layer 340 may be interrupted. The buried layer 340 grows from a m-plane of the columnar semiconductor 130. Therefore, the space ZI is formed at a middle point of the columnar semiconductors 130 arranged in a square lattice. The space Z1 has a shape occupying the inside of the hexagonal cylinder.

### 4. Effect of Third Embodiment

In a laser device having the above structure, when a current injected exceeds the threshold current, induced emission is generated from the active layer having a m-plane. Thereby, laser oscillation is generated in a direction perpendicular to a cross section of XVII-XVII and a cross section of XVIII-XVIII. In this case, the relative tendency of the lateral (column, x-axis) distribution of the refractive index in the waveguide is close between the cross section of XVII-XVII and the cross section of XVIII-XVIII. Therefore, light scattering loss is reduced when a laser light is guided in a longitudinal (row, y-axis) direction. Thereby, slope efficiency is improved.

FIGS. 19A and 19B are a diagram showing the case when the n-type columnar semiconductor 131 is laterally arranged in three rows. FIG. 19B shows the light intensity on a cross section of XIX-XIX in FIG. 19A. Here, curve L1 shows the light intensity in the semiconductor light-emitting device 300 according to the third embodiment, i.e., lateral mode distribution. Curve L2 shows the light intensity (lateral mode distribution) in the semiconductor light-emitting device when there is no space Z1. By bringing the relative characteristics of the lateral distribution of the refractive index close between the cross section of XVII-XVII with n-type columnar semiconductor 131 and the cross section of XVIII-XVIII without the columnar semiconductor 130, light scattering loss can be reduced. Therefore, standing wave in the longitudinal direction is stably formed. Thereby, a super single mode having a higher intensity is achieved.

As shown in FIGS. 19A and 19B, the light intensity is the maximum value at a position where the columnar semiconductor 130 (n-type columnar semiconductor 131) exists. That is, the light intensity is large at a position where the columnar semiconductor 130 exists. Moreover, the light intensity is the minimum value in a region between the columnar semiconductors 130. The light intensity is the largest in a vicinity of the center row of the three rows.

As shown in FIG. 19B, the local maximum values of a light indicated by curve L1 are larger than the local maximum values of a light indicated by curve L2. Moreover, the local minimum values of a light indicated by curve L1 are smaller than the local minimum values of a light indicated by curve L2.

In the semiconductor light-emitting device 300, a bright light can pass through the rows of the columnar semiconductor 130. Therefore, for example, when a laser is oscillated by reflecting a light at the end surfaces S1 and S2 and reciprocating a light in a direction of arrow A1 in FIG. 1, a laser light of high intensity can be oscillated.

Thus, by controlling the refractive index in a region where the columnar semiconductor 130 does not exist, the light intensity can be increased at a position where the columnar semiconductor 130 exists.

### 5. Variations

### 5-1. Pit

A pit may be formed instead of space Z1. The pit may have a V-type shape constituting a {10-1x} plane or a {11-2y} plane inclined with respect to a {0001} plane of Group III nitride semiconductor. The pit may have a shape constituting a plane perpendicular to a {0001} plane such as a {10-10} plane or a {11-20} plane. Needless to say, the pit may have a shape formed by combining an inclined plane and a perpendicular plane. These pits preferably have the same shape. In this case, the average refractive index is the same in that region. Thereby, more stable standing wave can exist.

### 5-2. Others

The variations of the first embodiment may be employed. For example, the same effect is obtained when the space Z1 or the pit is filled with a layer having a refractive index lower than that of the buried layer 340. For example, when the buried layer 340 is GaN, the space Z1 or the pit may be filled with an AlGaN layer having a refractive index smaller than that of GaN or a transparent electrode such as ITO. In this case, the flatter the surface after burying, the better. The subsequent process such as electrode formation or device formation is facilitated.

### Fourth Embodiment

The fourth embodiment will next be described. Points different from the first embodiment will be mainly described.

### 1. Semiconductor Light-Emitting Device

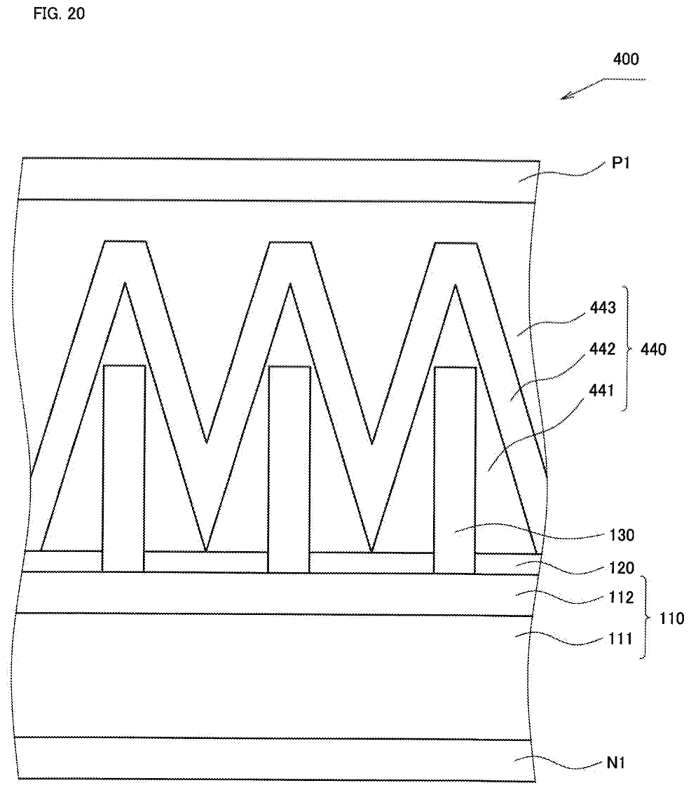

FIG. 20 is a schematic view of the structure of a semiconductor light-emitting device 400 according to a fourth embodiment. As shown in FIG. 20, the semiconductor light-emitting device 400 includes a substrate 110, a mask 120, a columnar semiconductor 130, a buried layer 440, a cathode electrode N1, and an anode electrode P1.

The buried layer 440 has a first layer 441, a second layer 442, and a third layer 443. The first layer 441, the second layer 442, and the third layer 443 is an n-type semiconductor layer, for example, n-type GaN.

The first layer 441 covers the columnar semiconductor 130. The second layer 442 covers the first layer 441. The third layer 443 covers the second layer 442. The second layer 442 is sandwiched between the first layer 441 and the third layer 443. The third layer 443 is in contact with the anode electrode P1.

The Si concentration of the second layer 442 is higher than the Si concentration of the first layer 441. The Si concentration of the third layer 443 is higher than the Si concentration of the second layer 442. The Si concentration of the first layer 441 is, for example, 1×10¹⁷ cm⁻³ to 2×10¹⁸ cm⁻³. The Si concentration of the second layer 442 is, for example, 2×10¹⁸ cm⁻³ to 5×10¹⁸ cm⁻³. The Si concentration of the third layer 443 is, for example, 5×10¹⁸ cm⁻³ to 5×10¹⁹ cm⁻³.

### 2. Method for Producing Semiconductor Light-Emitting Device

When the buried layer 440 is grown, the amount of a dopant gas containing Si may be increased. The dopant gas may be increased gradually or stepwisely.

### 3. Effect of Fourth Embodiment

The impurity concentration is low in a vicinity of the columnar semiconductor 130 inside the buried layer 440. Therefore, a light is hardly absorbed in a vicinity of the columnar semiconductor 130. The reduction of the light extraction efficiency is suppressed in LED. In the laser diode (LD), the increase of a threshold current and the reduction of a gain are suppressed. Here, a vicinity of the columnar semiconductor 130 is, for example, the first layer 441.

In a region farther from the columnar semiconductor 130 inside the buried layer 440, the impurity concentration is high. In this region, the electrical resistivity is low. Therefore, a current easily flows. Here, a region farther from the columnar semiconductor 130 inside the buried layer 440 is, for example, the third layer 443. In a region laterally farther from the columnar semiconductor 130 inside the buried layer 440, a light may be absorbed on account of a high impurity concentration. However, a light passing through the third layer 443 does not contribute to laser oscillation. Therefore, absorption of the light in the area of the third layer 443 hardly affects the threshold current or the gain in LD.

That is, in the semiconductor light-emitting device 400, the increase of the threshold current and the reduction of the gain are suppressed because a current easily flows into the active layer 132 and light absorption is reduced.

### 4. Variations

### 4-1. When Tunnel Junction Part Does Not Exist

When a tunnel junction part does not exist, the buried layer for filling in a space between the columnar semiconductors 130 is a p-type layer. Even in this case, the Mg concentration in a vicinity of the columnar semiconductor 130 may be reduced, and the Mg concentration may be increased as the distance from the columnar semiconductor 130 increases. The Mg concentration of the first layer is, for example, 1×10¹⁸ cm⁻³ to 5×10¹⁹ cm⁻³. The Mg concentration of the second layer is, for example, 5×10¹⁹ cm⁻³ to 1×10²⁰ cm⁻³. The Mg concentration of the third layer is, for example, 1×10²⁰ cm⁻³ to 5×10²⁰ cm⁻³.

When a space between the columnar semiconductors 130 is filled with the p-type layer, in addition to the above, a p-type contact layer in contact with the anode electrode P1 may be formed. The Mg concentration of the p-type contact layer is, for example, 5×10²⁰ cm⁻³ to 5×10²¹ cm⁻³.

### 4-2. Others

Variations of the first embodiment may be employed.

### Fifth Embodiment

The fifth embodiment will next be described. Points different from the first embodiment are mainly described.

### 1. Semiconductor Light-Emitting Device

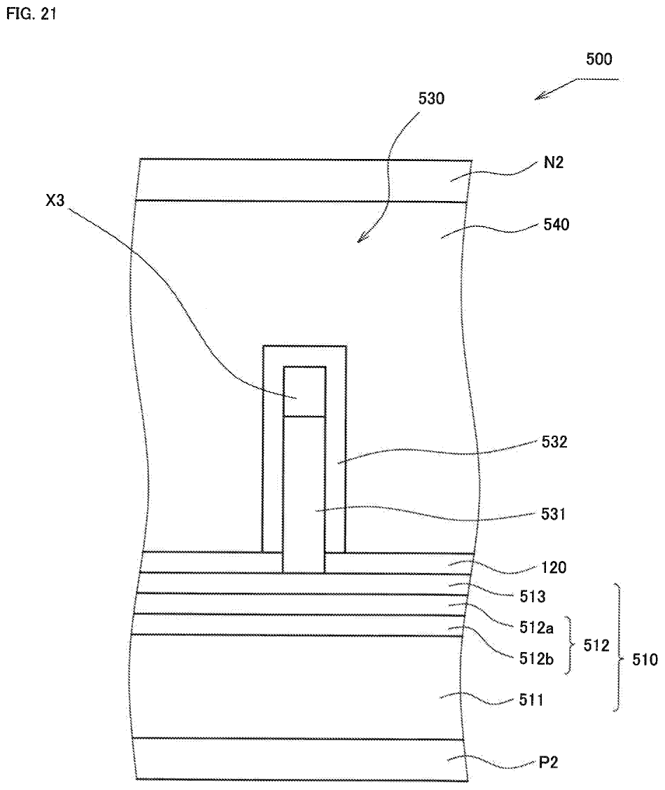

FIG. 21 is a schematic view of the structure of a semiconductor light-emitting device 500 according to a fifth embodiment. As shown in FIG. 21, the semiconductor light-emitting device 500 includes a substrate 510, a mask 120, a columnar semiconductor 530, a buried layer 540, a cathode electrode N2, and an anode electrode P2.

The substrate 510 has an n-type semiconductor layer 511, a tunnel junction part 512, and a p-type semiconductor layer 513. The n-type semiconductor layer 511 is, for example, an n-type GaN layer. The p-type semiconductor layer 513 is, for example, a p-type GaN layer.

The tunnel junction part 512 has a p⁺-type layer 512a and an n⁺-type layer 512b. The p⁺-type layer 512a is disposed between the n⁺-type layer 512b and the p-type semiconductor layer 513. The n⁺-type layer 512b is disposed between the n-type semiconductor layer 511 and the p⁺-type layer 512a. The p⁺-type layer 512a is, for example, a p-type GaN layer. The n⁺-type layer 512b is, for example, an n-type GaN layer. The Mg concentration of the pt-type layer 512a is higher than the Mg concentration of the p-type semiconductor layer 513. The Si concentration of the n⁺-type layer 512b is higher than the Si concentration of the n-type semiconductor layer 511.

The columnar semiconductor 530 has a p-type columnar semiconductor 531 and an active layer 532. The p-type columnar semiconductor 531 is, for example, a p-type GaN layer.

The buried layer 540 is filled in a space between the columnar semiconductors 530. The buried layer 540 is an n-type semiconductor layer. The buried layer 540 is, for example, an n-type GaN layer.

The cathode electrode N2 is formed on the buried layer 540. The anode electrode P2 is formed on the substrate 510.

### 2. Effect of Fifth Embodiment

Even in this case, the same effect as in the first embodiment is obtained.

### 3. Variations

The fifth embodiment may be combined with the variations of the first embodiment.

### Combination of Embodiments

The first embodiment to the fifth embodiment may be combined with one another.

What is claimed is:

1. A semiconductor light-emitting device comprising:
a base layer;
a plurality of columnar semiconductors on the base layer;
a buried layer filling in a space between the columnar semiconductors; and
a current suppression region suppressing a current, wherein
the plurality of columnar semiconductors has a hexagonal column, and an active layer covering the hexagonal column,
the hexagonal column has a hexagonal first surface and a second surface opposite to the first surface,
the first surface of the columnar semiconductors faces the base layer, and
the second surface of the columnar semiconductors faces the current suppression region.

2. The semiconductor light-emitting device according to claim 1, wherein the current suppression region is a semiconductor having an electrical resistivity higher than the electrical resistivity of the columnar semiconductors.

3. The semiconductor light-emitting device according to claim 1, wherein the current suppression region is a space.

4. The semiconductor light-emitting device according to claim 1, wherein the columnar semiconductor is arranged in a plane lattice, and a space or a pit is formed in a region disposed at a face center of a unit cell of the plane lattice.

5. The semiconductor light-emitting device according to claim 1, wherein
the buried layer has a first layer covering the columnar semiconductors, and a second layer covering the first layer, and
the impurity concentration of the second layer is higher than the impurity concentration of the first layer.

6. The semiconductor light-emitting device according to claim 1, wherein
a tunnel junction part is formed,
the tunnel junction part has a p-type layer and an n-type layer, and
the tunnel junction part is disposed between the active layer and the buried layer.

7. The semiconductor light-emitting device according to claim 1, wherein
an anode electrode and a conductive oxide layer are formed,
the conductive oxide layer is disposed between the buried layer and the anode electrode.
